(19) United States
(12) Patent Application Publication
(10) Pub. No.: US 2024/0233969 A9
(43) Pub. Date: Jul. 11, 2024

(54) Apparatus and Method for Diganosis and Prediction of Severe Accidents in Nuclear Power Plant using Artificial Intelligence and Storage Medium Storing Instructions to Performing Method for Digonosis and Prediction of Severe Accidents in Nuclear Power Plant

(71) Applicant: KOREA ATOMIC ENERGY RESEARCH INSTITUTE, Daejeon (KR)

(72) Inventors: Sung-yeop KIM, Daejeon (KR); Soo Yong PARK, Daejeon (KR)

(21) Appl. No.: 18/490,034

(22) Filed: Oct. 19, 2023

(30) Foreign Application Priority Data
Oct. 20, 2022 (KR) 10-2022-0135901
Apr. 27, 2023 (KR) 10-2023-0055698
Oct. 18, 2023 (KR) 10-2023-0139685

(51) Int. Cl. G21D 3/04; G21D 3/00

(52) U.S. Cl. CPC G21D 3/04; G21D 3/001

(57) ABSTRACT

Provided is an apparatus for diagnosis and prediction of a severe accident in a nuclear power plant. The apparatus comprises a classification unit configured to derive a plurality of scenarios for diagnosis and prediction of the severe accident in the nuclear power plant; a strorage medium storing instructions for executing a method for diagnosis and prediction of the severe accident in the nuclear power plant using a learning model trained by a training database including training input variables for the plurality of scenarios and severe accident diagnosis and prediction information corresponding to the training input variables; and a processor configured to obtain diagnostic input variables for the diagnosis and prediction of the severe accident in the nuclear power plant, input the diagnostic input variables into the learning model to check the severe accident diagnosis and prediction information, and output the checked severe accident diagnosis and prediction information.

### CROSS REFERENCE TO RELATED APPLICATION

The present application claims priority to Korean Patent Application No. 10-2022-0135901 filed Oct. 20, 2022, and Korean Patent Application No. 10-2023-0055698 filed Apr. 27, 2023, and Korean Patent Application No. 10-2023-0139685 filed Oct. 18, 2023, the entire contents of which are incorporated herein for all purposes by this reference.

### TECHNICAL FIELD

The present disclosure relates to technology for diagnosing and predicting severe accidents in a nuclear power plant based on an artificial intelligence learning model, and relates to artificial intelligence learning therefor.

This work was supported by a National Research Foundation of Korea (NRF) grant funded by Korea government (MSIT: Ministry of Science and ICT) (Project No.: RS-2022-00144405).

### BACKGROUND

A severe accident in a nuclear power plant is an accident that causes massive damage to a nuclear fuel in a reactor vessel and is defined in the Nuclear Safety Act as an accident that exceeds design standards and causes significant damage to the reactor core. Although the likelihood of a severe accident occurring is very low, it may deteriorate the integrity of physical barriers that prevent external leakage of radioactive materials, resulting in significant release of the radioactive materials outside the reactor core and containment building. Examples of representative sever accidents include the Three Mile Island (TMI) nuclear power plant accident in the United States in 1979, the Chernobyl nuclear power plant accident in the former Soviet Union in 1986, and the Fukushima nuclear power plant accident in Japan in 2011.

When such a severe accident has occurred at a nuclear power plant, diagnosis of the situation of the severe accident, prediction of the progress of the accident, and prediction of information on radioactive materials that can be released into the environment (defined as a source term which includes various types of information such as type, amount, energy, and particle size distribution) can be considered very important for accident management and emergency response.

### BRIEF SUMMARY

The present disclosure provides an apparatus and method for diagnosing and predicting a severe accident in a nuclear power plant using a learning model based on artificial intelligence, for example, machine learning.

The present disclosure proposes a learning technology for training an artificial intelligence model to diagnose and predict a severe accident at a nuclear power plant, specifically to diagnose a severe accident, predict the progress of a severe accident, and predict a source term.

The aspects of the present disclosure are not limited to the foregoing, and other aspects not mentioned herein will be clearly understood by those skilled in the art from the following description.

In accordance with an aspect of the present disclosure, there is provided an apparatus for diagnosis and prediction of a severe accident in a nuclear power plant, the apparatus comprises: a classification unit configured to derive a plurality of scenarios for diagnosis and prediction of the severe accident in the nuclear power plant; a strorage medium storing instructions for executing a method for diagnosis and prediction of the severe accident in the nuclear power plant using a learning model trained by a training database including training input variables for the plurality of scenarios and severe accident diagnosis and prediction information corresponding to the training input variables; and a processor executing the one or more instructions stored in the strorage medium, wherein the instructions, when executed by the processor, cause the processor to obtain diagnostic input variables for the diagnosis and prediction of the severe accident in the nuclear power plant, input the diagnostic input variables into the learning model to check the severe accident diagnosis and prediction information, and output the checked severe accident diagnosis and prediction information.

The learning model may include a severe accident prediction learning model trained to receive the training input variables, predict changes in the training input variables, and output a severe accident prediction result; and a source term prediction learning model trained to receive the training input variables and output a source term prediction result for predicting radioactive material release information.

The learning model may include a severe accident diagnosis learning model trained to classify the training input variables corresponding to the scenarios and outputs a severe accident diagnosis result, the severe accident prediction learning model may be trained to output results of prediction of changes in the training input variables on the basis of the severe accident diagnosis result provided from the severe accident diagnosis learning model, and the source term prediction learning model may be trained to output the source term prediction result for predicting radioactive material release information on the basis of the training input variables for the scenarios with respect to the severe accident diagnosis result provided from the severe accident diagnosis learning model.

The diagnostic input variables may include time series data related to status information of the nuclear power plant.

The scenarios may be derived based on probabilistic safety assessment (PSA).

The scenarios may be classified into detailed scenario of initiating events according to the probabilistic safety assessment on the basis of a plant damage state event tree (PDS ET) technique.

The processor may be configured to construct the training database in which uncertainty is analyzed for each of the scenarios and stores the training database in a database unit.

The uncertainty may include phenomenon analysis code uncertainty and analysis scenario uncertainty.

In accordance with another aspect of the present disclosure, there is provided a method for diagnosis and prediction of a severe accident in a nuclear power plant performed by an apparatus for diagnosis and prediction of a a severe accident in a nuclear power plant including a memory and a processor, the apparatus configured to derive a plurality of scenarios for diagnosis and prediction of the severe accident in the nuclear power plant, and store a learning model trained using a training database including training input variables for the plurality of scenarios and severe accident diagnosis and prediction information corresponding to the training input variables, the method comprises: obtaining diagnostic input variables for the diagnosis and prediction of the severe accident in the nuclear power plant; and performing processing to input the diagnostic input variables into the learning model in the memory to check the severe accident diagnosis and prediction information and output the checked severe accident diagnosis and prediction information.

The learning model may include a severe accident prediction learning model trained to receive the training input variables, predict changes in the training input variables, and output a severe accident prediction result; and a source term prediction learning model trained to receive the training input variables and output a source term prediction result for predicting radioactive material release information.

The learning model may include a severe accident diagnosis learning model trained to classify the training input variables corresponding the scenarios and output a severe accident diagnosis result, and the performing processing may include outputting results of prediction of changes in the diagnostic input variables on the basis of the severe accident diagnosis result provided from the severe accident diagnosis learning model using the severe accident prediction learning model; and outputting a source term prediction result for predicting radioactive material release information on the basis of the diagnostic input variables for the scenarios with respect to the severe accident diagnosis result provided from the severe accident diagnosis learning model using the source term prediction learning model.

The diagnostic input variables may include time series data related to status information of the nuclear power plant.

The scenarios may be derived based on probabilistic safety assessment.

The scenarios may be classified into detailed scenario of initiating events according to the probabilistic safety assessment on the basis of a plant damage state event tree technique.

The method may include constructing the training database in which uncertainty is analyzed for each of the scenarios.

The uncertainty includes phenomenon analysis code uncertainty and analysis scenario uncertainty.

In accordance with another aspect of the present disclosure, there is provided a non-transitory computer-readable recording medium storing a computer program, which comprises instructions for a processor to perform a method for training a learning model for diagnosis and prediction of a severe accident in a nuclear power plant, the method comprises preparing the learning model including a severe accident prediction learning model and a source term prediction learning model; selecting training input variables for the diagnosis and prediction of the severe accident in the nuclear power plant; deriving a plurality of scenarios for the diagnosis and prediction of the severe accident in the nuclear power plant; constructing a training database for each scenario; inputting the training input variables into the severe accident prediction learning model and training the severe accident prediction learning model to predict changes in the training input variables and output a severe accident prediction result; and inputting the training input variables into the source term prediction learning model and training the source term prediction learning model to predict radioactive material release information and output a source term prediction result.

According to an embodiment of the present disclosure, it is possible to systematically and efficiently apply nuclear power plant severe accident scenarios with the number of various cases and to sufficiently consider phenomenological uncertainty inherent in producing big data for accident diagnosis and accident prediction in nuclear power plants by providing a severe accident diagnosis and prediction environment for nuclear power plants using a learning model based on artificial intelligence and proposing a learning technology for training an artificial intelligence model to perform diagnosis of a severe accident at a nuclear power plant, severe accident prediction, and source term prediction.

In addition, according to an embodiment of the present disclosure, it is possible to perform a timely accident management strategy (guideline), and after rapid/accurate accident diagnosis and accident prediction, predict even an accident source term which is information on release of radioactive materials to support optimized decision-making for resident protection measures around a nuclear power plant.

### BRIEF DESCRIPTION OF THE DRAWINGS

FIG. 1 is a block diagram for functionally describing a severe accident diagnosis and prediction apparatus according to an embodiment of the present disclosure.

FIG. 2 is a diagram illustrating a detailed configuration of a severe accident diagnosis and prediction program included in a storage in the severe accident diagnosis and prediction apparatus of FIG. 1.

FIG. 3 is a diagram illustrating a severe accident diagnosis learning model in the severe accident diagnosis and prediction program of FIG. 2.

FIG. 4 is a diagram illustrating a severe accident prediction learning model in the severe accident diagnosis and prediction program of FIG. 2.

FIG. 5 is a diagram illustrating a source term prediction learning model in the severe accident diagnosis and prediction program of FIG. 2.

FIG. 6 is a flowchart illustrating a severe accident diagnosis and prediction method of the severe accident diagnosis and prediction apparatus according to an embodiment of the present disclosure.

FIG. 7 is a conceptual diagram illustrating detailed scenarios classified based on a plant damage state event tree (PDS ET) technique in a scenario derivation process of FIG. 6.

FIG. 8 is a conceptual diagram illustrating a problem of classifying detailed scenarios with respect to initiating events of a medium coolant loss accident through nuclear power plant data in a severe accident diagnosis process of FIG. 6.

FIG. 9 is a conceptual diagram illustrating a problem of predicting future nuclear power plant data through initial nuclear power plant data in a severe accident prediction process of FIG. 6.

FIGS. 10A to 10F are simulation graphs showing results of predicting water levels and pressures in a reactor building with respect to a detailed scenario of a medium coolant loss accident in the severe accident prediction process of FIG. 6.

FIG. 11 is a conceptual diagram illustrating a problem of predicting cumulative environmental release of major elements through nuclear power plant data in a source term prediction process of FIG. 6.

FIGS. 12A to 12F, and FIGS. 13A to 13F are conceptual diagrams illustrating a source term prediction problem for major elements (Xe, I, and Cs) with respect to a detailed scenario of a medium coolant loss accident in the source term prediction process.

### DETAILED DESCRIPTION

The advantages and features of the embodiments and the methods of accomplishing the embodiments will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

Terms used in the present specification will be briefly described, and the present disclosure will be described in detail.

In terms used in the present disclosure, general terms currently as widely used as possible while considering functions in the present disclosure are used. However, the terms may vary according to the intention or precedent of a technician working in the field, the emergence of new technologies, and the like. In addition, in certain cases, there are terms arbitrarily selected by the applicant, and in this case, the meaning of the terms will be described in detail in the description of the corresponding invention. Therefore, the terms used in the present disclosure should be defined based on the meaning of the terms and the overall contents of the present disclosure, not just the name of the terms.

When it is described that apart in the overall specification “includes” a certain component, this means that other components may be further included instead of excluding other components unless specifically stated to the contrary.

In addition, a term such as a “unit” or a “portion” used in the specification means a software component or a hardware component such as FPGA or ASIC, and the “unit” or the “portion” performs a certain role. However, the “unit” or the “portion” is not limited to software or hardware. The “portion” or the “unit” may be configured to be in an addressable storage medium, or may be configured to reproduce one or more processors. Thus, as an example, the “unit” or the “portion” includes components (such as software components, object-oriented software components, class components, and task components), processes, functions, properties, procedures, subroutines, segments of program code, drivers, firmware, microcode, circuits, data, database, data structures, tables, arrays, and variables. The functions provided in the components and “unit” may be combined into a smaller number of components and “units” or may be further divided into additional components and “units”.

Hereinafter, the embodiment of the present disclosure will be described in detail with reference to the accompanying drawings so that those of ordinary skill in the art may easily implement the present disclosure. In the drawings, portions not related to the description are omitted in order to clearly describe the present disclosure.

When a severe accident has occurred at a nuclear power plant, it is very important to diagnose the situation of the severe accident and predict the progress and source term information which is information on radioactive materials that can be released into the environment (including various types of information such as type, amount, energy, and particle size distribution) for accident management and emergency response.

At the time of the Fukushima accident, Japan had a decision-making system for resident protection measures called SPEEDI (system for prediction of environmental emergency dose information), but it was not utilized and the lack of provision of source term information was a major reason. Korea also has a system called AtomCARE (computerized technical advisory system for a radiological emergency) which is a nuclear disaster management system, and it is very important to derive source term information through information received from the power plant in an accident situation prior to atmospheric diffusion and dose calculation for decision-making for resident protection measures.

In existing methods for diagnosing severe accidents and predicting accident source terms, such as RASTEP (rapid source term prediction), the most likely scenario is found and source term information corresponding to that scenario from a database (DB) calculated and constructed in advance is provided. However, these methods have limitations in that pre-constructed scenarios are limited, multiple scenarios can be selected rather than just one, and pre-calculated source term information is also limited and has large uncertainties.

As described above, according to conventional technology, the most likely scenario is selected from limited scenarios assumed in advance through information that can be received from a power plant in an accident situation, and source term information constructed through pre-calculation for that scenario is provided. As a result, the information is considerably limited and uncertainty is high.

To overcome such limitations, an embodiment of the present disclosure proposes a technology for performing severe accident diagnosis, accident prediction, and source term prediction in a nuclear power plant by incorporating artificial intelligence technology.

For a successful accident management support system, it is necessary to systematically and efficiently derive a wide variety of severe accident scenarios, consider phenomenological uncertainty inherent in producing big data for accident diagnosis and accident prediction, and provide rapid and accurate information for decision making of technical support personnel for preventing and mitigating accidents.

In addition, as an approach (differentiation) of the present disclosure to meet the requirements, scenarios in which a severe accident may occur can be systematically derived through a probabilistic safety assessment (PSA) technique, and representative severe accident scenarios can be classified and derived using a plant damage state event tree (PDS ET) technique of level-2 PSA.

In addition, in an embodiment of the present disclosure, a database is constructed using severe accident comprehensive analysis code with well-defined phenomenological uncertainty variables and ranges thereof for analysis of thermal hydraulic/severe accident phenomenological uncertainty related to accident progress, and an artificial intelligence technique is applied to support decision making through rapid and accurate ascertainment of severe accident situations.

Hereinafter, embodiments of the present disclosure will be described in detail with reference to the attached drawings.

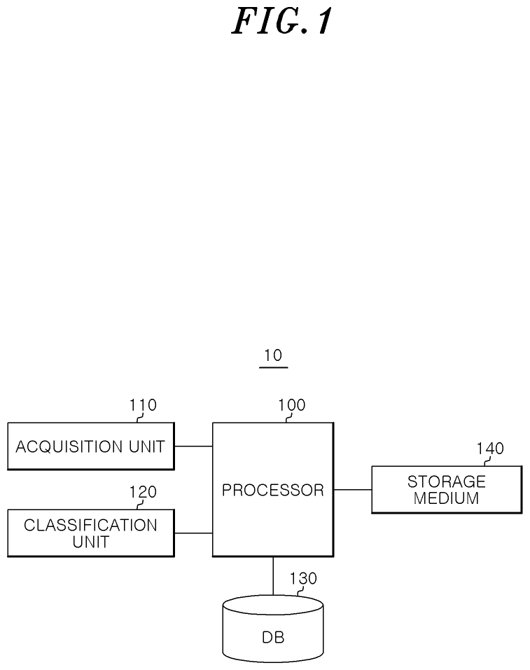

FIG. 1 is a block diagram for functionally describing a severe accident diagnosis and prediction apparatus 10 according to an embodiment of the present disclosure.

As shown in FIG. 1, the severe accident diagnosis and prediction apparatus 10 may include a processor 100, an acquisition unit 110, a classification unit 120, a database 130, and a storage 140. This severe accident diagnosis and prediction apparatus may include, for example, atypical computing environment such as a desktop personal computer (PC) or a server and various mobile computing environments such as a laptop PC, a netbook computer, a tablet PC, and a smartphone.

When input variables are acquired through the acquisition unit 110, the processor 100 may perform processing such that severe accident diagnosis and prediction information is output through a learning model in a program stored in the storage 140. This processor 100 may include, for example, a microprocessor-based computing device, perform diagnosis and prediction of a severe accident in a nuclear power plant using a learning model, and train the learning model to diagnose a severe accident at a nuclear power plant, predict the progress of the severe accident, and predict a source term according to an embodiment of the present disclosure. In addition, the processor 100 may control the overall operation of the severe accident diagnosis and prediction apparatus 10, for example, user interface (UI) operation according to input/output, display output operation, data recording or loading operation, and the like.

The acquisition unit 110 may acquire and select various input variables for diagnosis and prediction of severe nuclear power plant accidents. For artificial intelligence learning, input variables and output variables are required. A vast amount of nuclear power plant information can be input in real time into a nuclear disaster management system (for example, AtomCARE in Korea), and the data type of this nuclear power plant information can be regarded as time series data that changes overtime. In an embodiment of the present disclosure, among such information, variables with highest correlation with severe accident diagnosis, prediction, and source term prediction may be selected as input variables for artificial intelligence learning.

The classification unit 120 may derive a plurality of scenarios for diagnosing and predicting severe accidents in the nuclear power plant. It is very important to systematically and efficiently derive various severe accident scenarios. In an embodiment of the present disclosure, severe accident scenarios can be derived through probabilistic safety assessment (PAS) and frequencies thereof can be calculated.

A training database may be constructed in the database 130 to analyze uncertainty for each scenario according to an embodiment of the present disclosure. Here, severe nuclear power plant accident analysis code may be used for the training database, and massive input of the severe accident analysis code may be developed for detailed severe accident scenarios and the training database may be constructed through massive computations. Massive databases can be constructed by performing uncertainty analysis related to phenomenon simulations and code uncertainty analysis of the severe accident analysis code itself for each detailed scenario. Here, the severe accident analysis code may be, for example, results of analysis for 72 hours from the time of an accident, and a database of input variables for artificial intelligence learning may also be constructed as results of severe accident analysis code computation.

Here, uncertainty analysis techniques can be divided into phenomenon analysis code uncertainty and analysis scenario uncertainty depending on an uncertain variable to be considered during analysis.

First, the phenomenon analysis code uncertainty can consider only phenomenological uncertainty variables inherent in computation code (MAAP) for analyzing severe nuclear power plant accident phenomena. For example, uncertainties in variables related to various heat transfer coefficients or reactor vessel rupture mechanisms can be considered. Uncertainties related to this are commonly applied to all analyses, and the number of related variables is usually expected to amount to dozens. Specific examples are as follows.
FWHL: Hot leg natural circulation flow rate correlation coefficient
TCLMAX: Temperature that will lead to rupture if the cladding is at this temperature for 36 seconds
HTSTAG: SG primary side heat transfer coefficient for a stagnant water pool when there is no forced or natural circulation
HTFB: Coefficient for film boiling heat transfer from corium to an overlying pool
TAUTO: Auto-ignition temperature for hydrogen and carbon monoxide burns

Next, analysis scenario uncertainty is an item for more effectively producing data for use in artificial intelligence learning by classifying accident scenarios according to the cause of a nuclear power plant accident and whether or not the safety system operates during an accident mitigation process.

The development of severe nuclear power plant accidents is very diverse and extensive. One of methodologies for most systematically classifying severe nuclear power plant accidents and quantifying their probabilities of occurrence is utilization of the PDS event tree of PSA. In the PDS event tree, scenarios that can cause severe accidents in nuclear power plants are broadly divided into dozens (for example, a primary system coolant loss accident (LOCA), a power plant power outage accident (SBO), an equipment coolant loss accident (TLOCCW), etc.) depending on causes, and the possibility of occurrence can be analyzed by dividing each of the scenarios into dozens of detailed scenarios depending on whether or not the safety system operates.

In order to produce data for accident prediction using artificial intelligence, the detailed scenarios described above are defined as unit scenarios, and hundreds of unit scenarios can be derived. Each unit scenario may have uncertainties related to the cause of an accident (e.g., a pipe rupture size during LOCA) and uncertainties related to accident mitigation (e.g., safety system operation time, etc.).

Meanwhile, depending on a PDS event tree analysis method (which event is divided from a branch for an initiating event), such uncertainties may be excluded (e.g., TLOCCW initiating event). At the time of analyzing each unit scenario, “phenomenon analysis code uncertainty” and “analysis scenario uncertainty” described above are simultaneously considered. Examples of uncertain variables associated with “analysis scenario uncertainty” for LOCA scenarios are as follows.
ABBN (1): pipe rupture area for LOCA
TIME_HPH: hot leg and cold leg recirculation start time of high pressure safety injection system

In order to produce data for artificial intelligence learning, it is necessary to perform hundreds of accident progress analyses for each unit scenario. In other words, analysis can be performed by determining the range and probability distribution of uncertain variable values, extracting hundreds of samples using stratified Latin hypercube sampling (LHS), and creating MAAP 5 scenario input reflecting the same. In example problems, some thereof were excluded from final data due to convergence issues, and 200 to 300 final data sets were produced for each unit scenario.

The storage 140 may store a program for providing severe accident diagnosis and prediction information according to input variables on the basis of a training database in the database 130 constructed for each scenario. Such a program may include a learning model capable of performing diagnosis of severe accidents, prediction of the progress of a severe accident, and prediction of a source term according to an embodiment of the present disclosure. The program stored in the storage 140 may be selected and loaded by the processor 100 or recorded or modified as necessary.

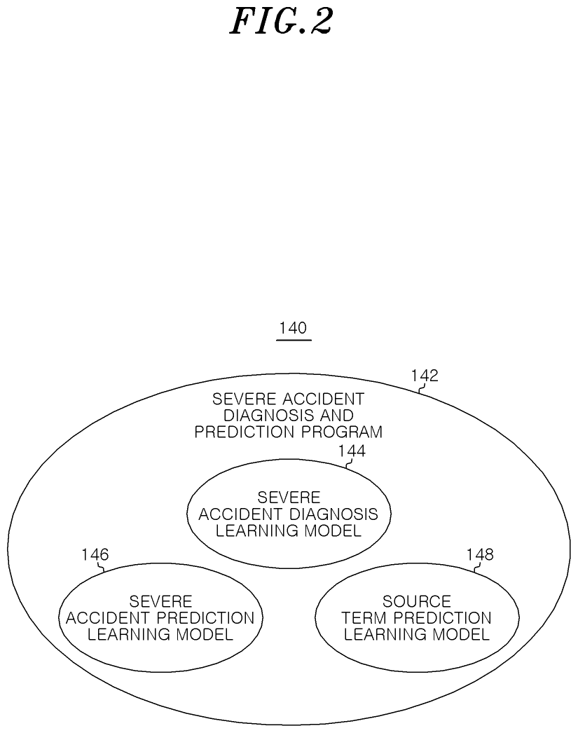

FIG. 2 is a diagram showing a detailed configuration of a learning model included in a severe accident diagnosis and prediction program 142 in the storage 140 in the severe accident diagnosis and prediction apparatus 10 of FIG. 1.

As shown in FIG. 2, the learning model in the severe accident diagnosis and prediction program 142 may include a severe accident prediction learning model 146 and a source term prediction learning model 148.

The severe accident prediction learning model 146 can output results of prediction of changes in the input variables. To this end, the processor 100 may input input variables into the severe accident prediction learning model 146, predict changes in the input variables, and train the learning model 146 such that the learning model 146 outputs severe accident prediction results.

The source term prediction learning model 148 can predict radioactive material release information based on input variables. To this end, the processor 100 can input input variables into the source term prediction learning model 148, predict radioactive material release information based on the input variables, and train the learning model 148 such that it outputs source term prediction results.

As another example, the learning model in the severe accident diagnosis and prediction program 142 may include a severe accident diagnosis learning model 144, the severe accident prediction learning model 146, and the source term prediction learning model 148.

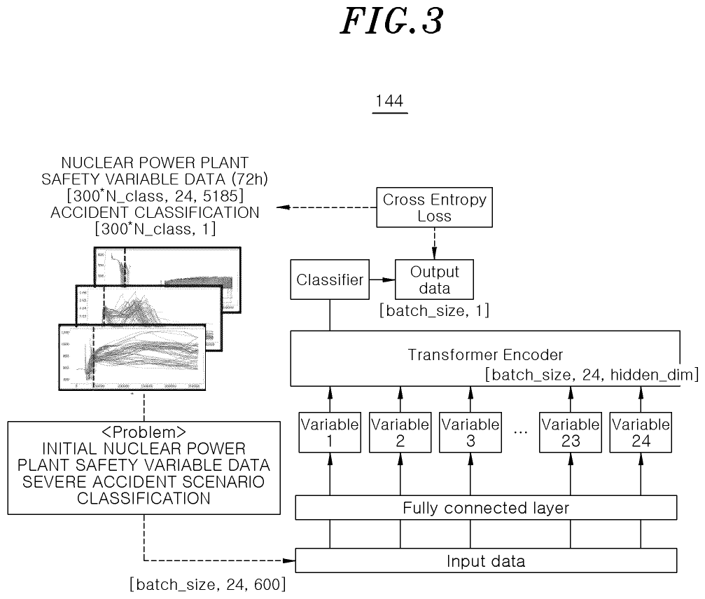

First, FIG. 3 is a diagram illustrating the severe accident diagnosis learning model 144 in the severe accident diagnosis and prediction program 142 of FIG. 2.

The severe accident diagnosis learning model 144 may classify input variables acquired through the acquisition unit 110 according to scenarios in the classification unit 120 and output severe accident diagnosis results. To this end, the processor 100 may train the severe accident diagnosis learning model 144 such that the learning model 144 classifies the input variables selected through the acquisition unit 110 according to scenarios and outputs severe nuclear power plant accident diagnosis results on the basis of the training database in the database 130.

As illustrated in FIG. 3, the severe accident diagnosis learning model 144 may include a fully connected layer for reducing 24 input variables selected through the acquisition unit 110 to a specific vector, a transformer encoder for extracting the characteristics of the input variables by compressing the 24 input variables that have passed through the fully connected layer into one vector representation, and a multi-layer perceptron (MLP) for converting the characteristics of the input variables extracted through the transformer encoder into output values. Here, a cumulative prediction method may be applied to the output values. In the cumulative prediction method, if the first value is set to 0, the second value is output as the first output value, the third value is output as the sum of the first and second output values, and the fourth value is output as the sum of the first, second and third output values.

The severe accident diagnosis learning model 144 may include, for example, an artificial intelligence model based on supervised learning and does not need to be limited to a specific learning model.

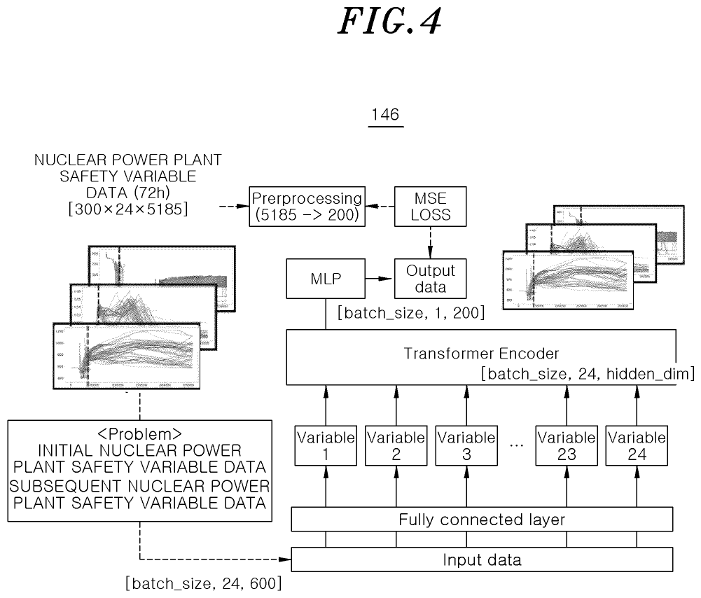

FIG. 4 is a diagram illustrating the severe accident prediction learning model 146 in the severe accident diagnosis and prediction program 142 of FIG. 2.

The severe accident prediction learning model 146 can output results of prediction of changes in the input variables selected through the acquisition unit 110 based on severe accident diagnosis results of the severe accident diagnosis learning model 144. To this end, the processor 100 may train the severe accident prediction learning model 146 such that the learning model 146 predicts changes in the input variables based on the severe accident diagnosis results of the severe accident diagnosis learning model 144 and outputs a severe accident prediction result.

As illustrated in FIG. 4, the severe accident prediction learning model 146 may include a fully connected layer for reducing 24 input variables selected through the acquisition unit 110 to a specific vector, a transformer encoder for extracting the characteristics of the input variables by compressing the 24 input variables that have passed through the fully connected layer into one vector representation, and an MLP for converting the characteristics of the input variables extracted through the transformer encoder into output values. Here, the aforementioned cumulative prediction method may be applied to the output values.

The severe accident prediction learning model 146 may include, for example, an artificial intelligence model based on supervised learning, and does not need to be limited to a specific learning model.

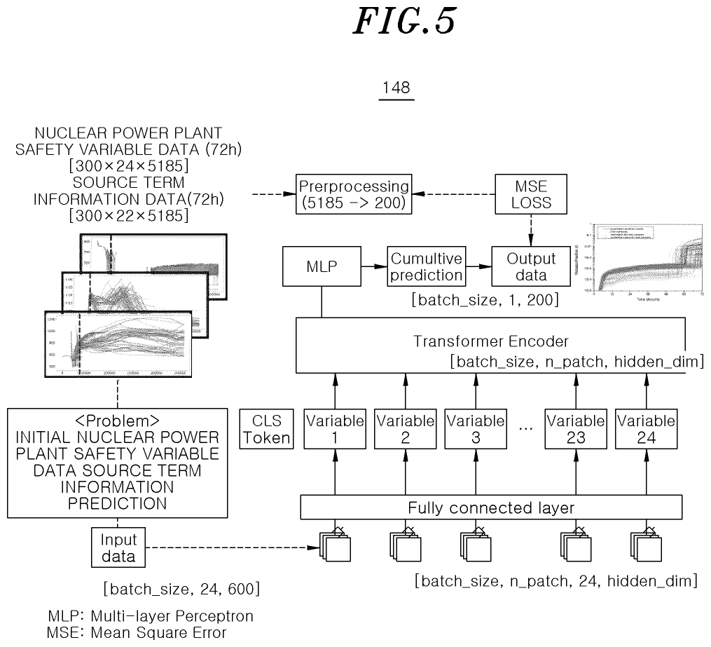

FIG. 5 is a diagram illustrating the source term prediction learning model 148 in the severe accident diagnosis and prediction program 142 of FIG. 2.

The source term prediction learning model 148 can predict radioactive material release information based on input variables for a scenario of a severe accident diagnosis result. To this end, the processor 100 may train the source term prediction learning model 148 such that the learning model 148 predicts radioactive material release information based on input variables for a scenario of a severe accident diagnosis result of the severe accident diagnosis learning model 144 and outputs source term prediction results.

As illustrated in FIG. 5, the source term prediction learning model 148 may divide 24 input variables (nuclear power plant safety variable data) each including 600 pieces of time data (approximately 30,000 seconds if time series data is set at 50 second intervals) by time into patches (for example, 24 input variables are composed of 6 patches each including 100 pieces of time data).

The relationship between these patches may be analyzed based on artificial intelligence through a transformer encoder, and as a result, an embedding vector representing the input variables (nuclear power plant safety variable data) may be generated. In an embodiment of the present disclosure, a source term can be predicted based on the corresponding embedding vector, and in this case, the cumulative prediction method can be applied to predict the source term. As illustrated in FIG. 5, the source term prediction learning model 148 may include a fully connected layer for reducing 24 input variables selected through the acquisition unit 110 to a specific vector, a transformer encoder for extracting the characteristics of the input variables by compressing the 24 input variables that have passed through the fully connected layer into one vector representation, and an MLP for converting the characteristics of the input variables extracted through the transformer encoder into output values. Here, the aforementioned cumulative prediction method may be applied to the output values.

In actual operation, by inputting 600 pieces of time data for 24 input variables, source term prediction results for 72 hours can be derived for each radioactive element.

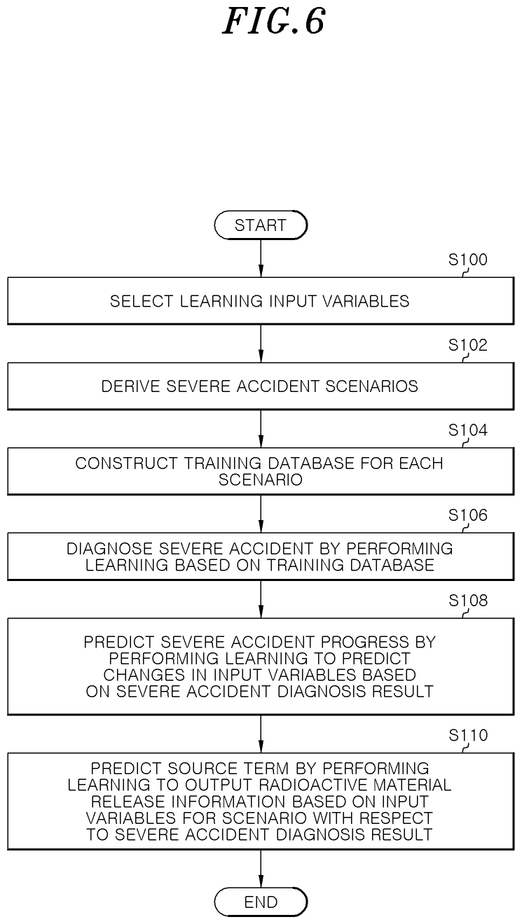

Hereinafter, a severe accident diagnosis and prediction method of the severe accident diagnosis and prediction apparatus 10 according to an embodiment of the present disclosure will be described in detail along with the above-described configuration with reference to FIGS. 6 to 13.

FIG. 6 is a flowchart illustrating the severe accident diagnosis and prediction method of the severe accident diagnosis and prediction apparatus 10 according to an embodiment of the present disclosure. A process of performing diagnosis of a severe accident in a nuclear power plant, prediction of the progress of the severe accident in a nuclear power plant, and prediction of a source term, and a process of training a learning model therefor will be described.

First, the acquisition unit 110 may acquire and select various input variables for diagnosing and predicting a severe accident (S100).

For artificial intelligence learning, input variables and output variables are required. A vast amount of nuclear power plant information can be input in real time into a nuclear disaster management system (for example, AtomCARE in Korea), and the data type of such nuclear power plant information can be regarded as time series data that changes over time. In an embodiment of the present disclosure, among such information, variables with a highest correlation with severe accident diagnosis, progress prediction, and source term prediction may be selected as input variables for artificial intelligence learning. Input variables that can be selected in an embodiment of the present disclosure may be as shown in Table 1 below.

TABLE 1

| No. | Variable definition | Unit |
|---|---|---|
| 1 | PRESSURIZER PRESS (WR) | kg/cm²(a) |
| 2 | PRESSURIZER LEVEL CH X | % |
| 3 | REACTOR VESSEL WATER LEVEL | |
| 4 | AVG TEMP OF HOT & COLD LEGS | ° C. |
| 5 | COLD LEG 1A MASS FLOW (1) | kg/h |
| 6 | COLD LEG 1B MASS FLOW (2) | kg/h |
| 7 | COLD LEG 2A MASS FLOW (3) | kg/h |
| 8 | COLD LEG 2B MASS FLOW (4) | kg/h |
| 9 | SG 1 PRESSURE CHA | kg/cm²(a) |
| 10 | SG 2 PRESSURE CHA | kg/cm²(a) |
| 11 | SG 1 LEVEL (WR) | % |
| 12 | SG 2 LEVEL (WR) | % |
| 13 | MAX REP CORE EXIT TEMP | ° C. |
| 14 | HIGHEST CET TEMP - CHANNEL A | ° C. |
| 15 | SAFETY INJ TANK PRESS (NR) | kg/cm²(a) |
| 16 | HPSI PUMP FLOW | L/min |
| 17 | LPSI PUMP DSCH HEADER FLOW | L/min |
| 18 | CONTAINMENT SPRAY FLOW | L/min |
| 19 | REFUELING WATER TANK LEVEL | % |
| 20 | CONTAINMENT PRESS CHA (NR) | cmH₂O(g) |
| 21 | CNMT AVERAGE TEMP | ° C. |
| 22 | CNMT WATER LEVEL CHA | % |
| 23 | CNMT RECIRC SUMP LEVEL CHA | % |
| 24 | H2 CONCENT. LEVEL (CH A) | % |

Table 1 shows 24 input variables related to nuclear power plant safety selected for artificial intelligence learning. These input variables are examples of specific variables to aid in understanding the embodiments of the present disclosure, and input variables may be flexibly added or deleted depending on the nuclear power plant system environment, severe accident diagnosis and prediction environment, and the like.

Subsequently, the classification unit 120 may derive a plurality of scenarios for diagnosing and predicting a severe accident (S102).

It is very important to systematically and efficiently derive various severe accident scenarios. In an embodiment of the present disclosure, severe accident scenarios can be derived and the frequencies thereof can be calculated through PAS.

Table 2 below illustrates scenarios of initiating events of severe accidents derived for an OPR1000 nuclear reactor.

TABLE 2

| Type | Initiating event |
|---|---|
| Coolant loss | Large coolant loss accident |
| accident | Medium coolant loss accident |
| | Small coolant loss accident |
| | Steam generator narrow pipe rupture |
| | Low pressure boundary coolant loss accident |
| | Reactor vessel rupture accident |
| Occurrences | Containment building internal main stream line failure |
| | accident |
| | Containment building external main stream line failure |
| | accident |
| | Main feed water loss accident |
| | Condenser vacuum loss accident |
| | Primary equipment cooling water partial loss accident |
| | Primary equipment cooling water total loss accident |
| | 1E 4.16 V AC bus A loss accident |
| | 1E 125 V DC bus A loss accident |
| | 1E 125 V DC bus B loss accident |
| | Off-site power loss accident |
| | Power plant power outage due to EDG startup failure |
| | Power plant power outage due to EDG failure during |
| | operation |
| | General occurrence |
| | Predicted non-stop occurrence |

An initial event is an event that can cause an unexpected shutdown of a nuclear reactor in a normally operating power plant. In nuclear power plant PSA, from this initiating event, detailed accident scenarios that may cause damage to a reactor core of a nuclear power plant can be classified using the PDS ET technique.

Each initiating event can be classified into detailed scenarios according to PDS ET.

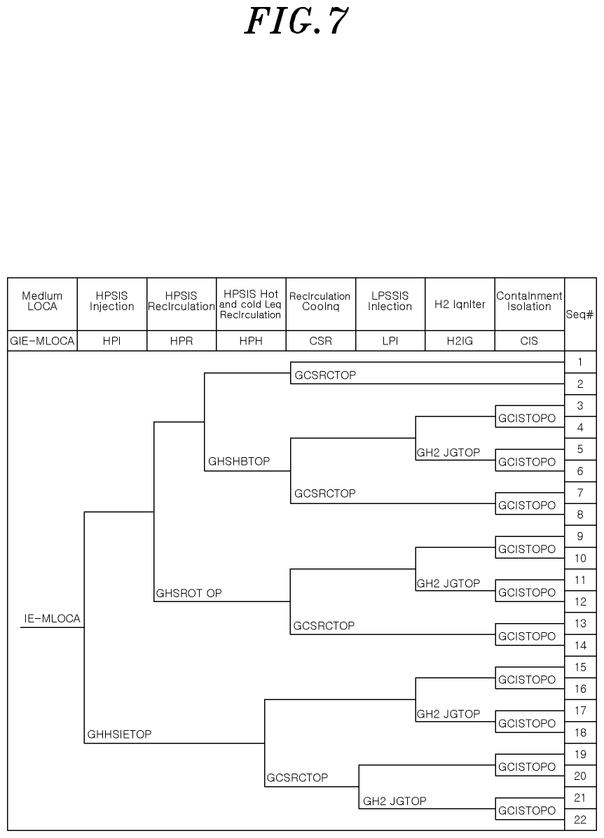

FIG. 7 is a conceptual diagram illustrating detailed scenarios classified based on the PDS ET technique in the scenario derivation process S102 of FIG. 6.

As illustrated in FIG. 7, several to dozens of detailed scenarios may be derived for each initiating event based on PDS ET, and the total number of detailed scenarios for all initiating events may range from tens to hundreds. The detailed scenarios include scenarios in which no severe accidents occur and scenarios whose frequency is negligible, and thus the number of scenarios that need to be focused on can be reduced by excluding such scenarios.

Referring back to FIG. 6, the severe accident diagnosis and prediction apparatus 10 may construct a training database in the database 130 for each scenario classified by the classification unit 120 (S104). A training database may be constructed in the database 130 to analyze uncertainty for each scenario according to an embodiment of the present disclosure, as described above.

When the training database for each scenario is constructed, the severe accident diagnosis and prediction apparatus 10 may classify input variables acquired through the acquisition unit 110 according to scenarios in the classification unit 120 on the basis of the constructed training database and output severe accident diagnosis results through the severe accident diagnosis learning model 144. To this end, the severe accident diagnosis and prediction apparatus 10 may train the severe accident diagnosis learning model 144 such that the learning model 144 classifies the input variables selected through the acquisition unit 110 according to scenarios and outputs severe accident diagnosis results on the basis of the training database in the database 130 (S106).

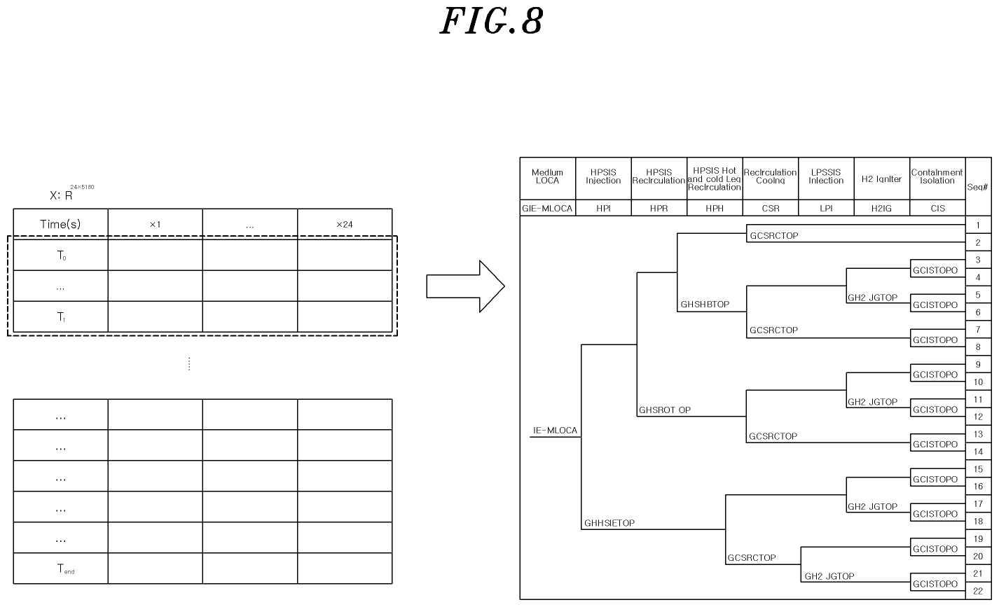

FIG. 8 is a conceptual diagram illustrating detailed scenario classification for an initiating event of a medium coolant loss accident through data in the severe accident diagnosis process S106 of FIG. 6.

Using the training database constructed through the database 130, an artificial intelligence model capable of classifying detailed scenarios defined by the classification unit 120 using input variables selected by the acquisition unit 110 may be created and trained. The input variables (nuclear power plant information from the power plant) of the acquisition unit 110 are composed of time series data, and as the length of data increases, the accuracy of scenario classification increases. The fact that each initiating event and a detailed scenario corresponding thereto can be classified through information received from a nuclear power plant means that a severe accident can be diagnosed through the information from the nuclear power plant. FIG. 8 shows a case in which detailed scenarios of an initiating event of a medium coolant loss accident are classified using information on the initial partial time among nuclear power plant information (for example, 24 pieces of time series data for 72 hours and 5180 step time series in units of 50 seconds) received from the nuclear power plant.

Thereafter, the severe accident diagnosis and prediction apparatus 10 may output results of prediction of changes in the input variables selected through the acquisition unit 110 on the basis of severe accident diagnosis results of the severe accident diagnosis learning model 144. To this end, the severe accident diagnosis and prediction apparatus 100 may train the severe accident prediction learning model 146 such that the learning model 146 predicts changes in the input variables on the basis of the severe accident diagnosis results of the severe accident diagnosis learning model 144 and outputs a severe accident prediction result (S108).

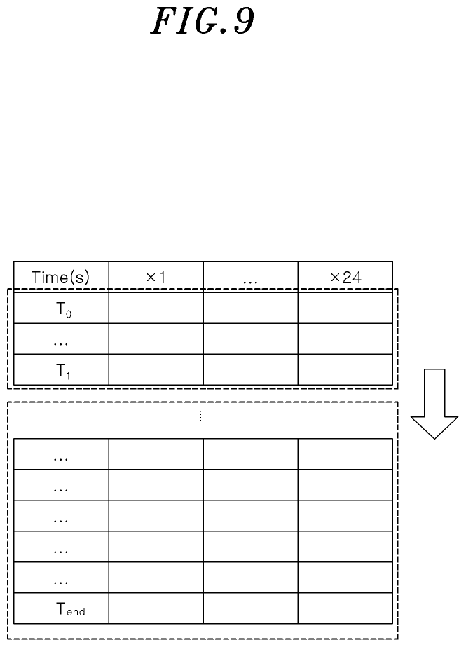

FIG. 9 is a conceptual diagram illustrating a problem of predicting future nuclear power plant data through initial nuclear power plant data in the severe accident prediction process S108 of FIG. 6.

When accident scenario classification is completed in step S106, that is, when diagnosis of a severe accident is completed, an artificial intelligence model may be created and trained to predict how the nuclear power plant variables defined in the acquisition unit 110 will change in a scenario of the severe accident. In other words, when a severe accident scenario is diagnosed, it is possible to predict how the nuclear power plant variables will change in the future using the current data on the nuclear power plant variables. As the time of incoming data increases, the prediction accuracy is improved.

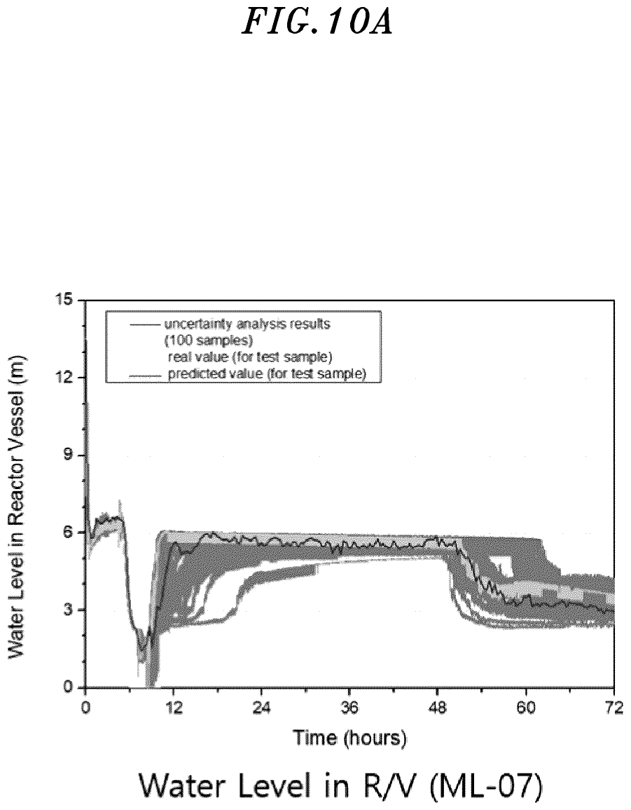

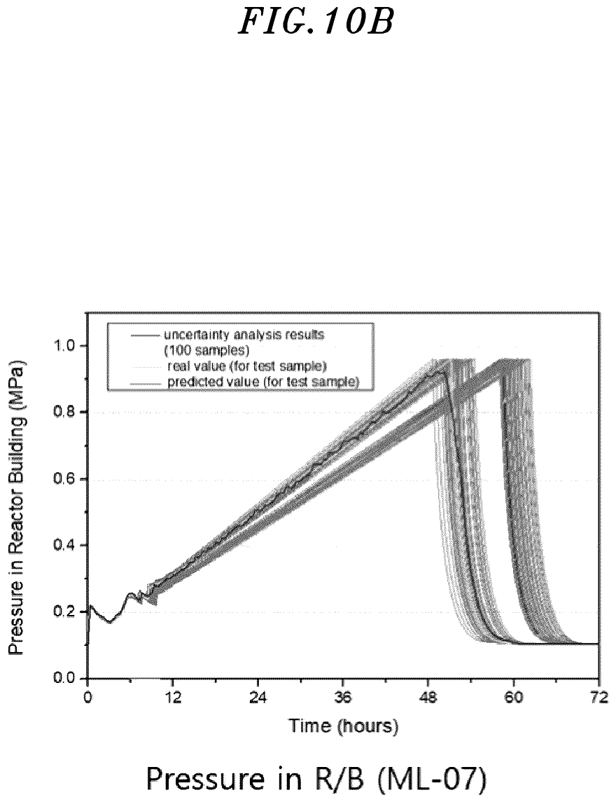

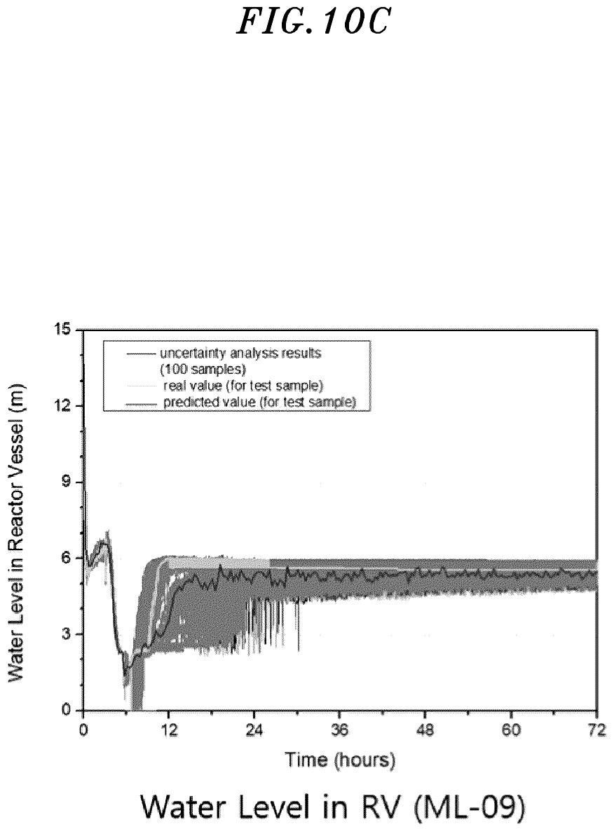

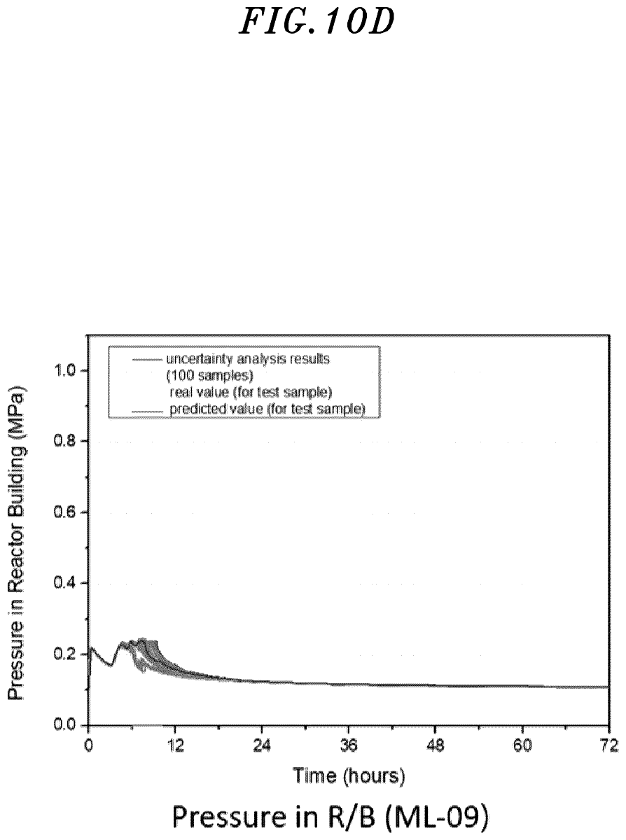

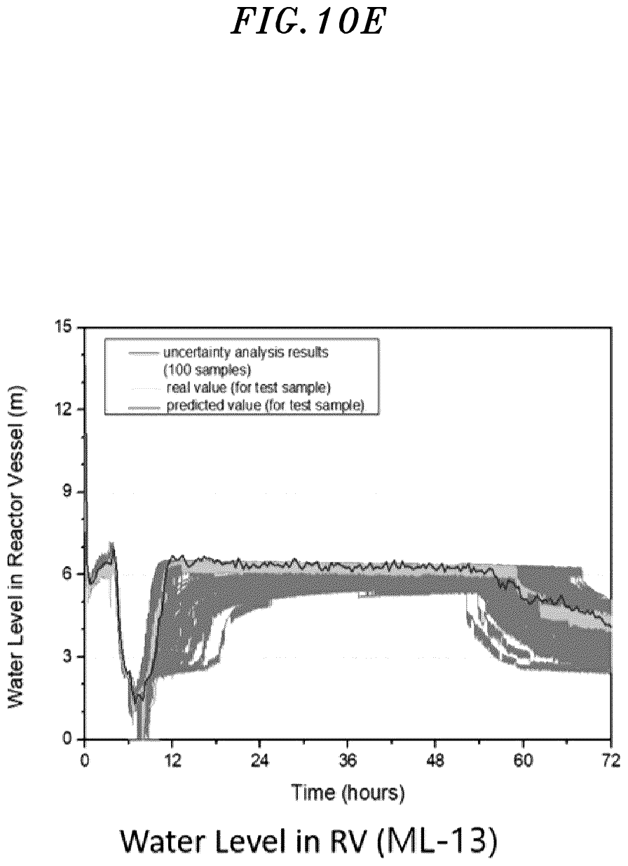

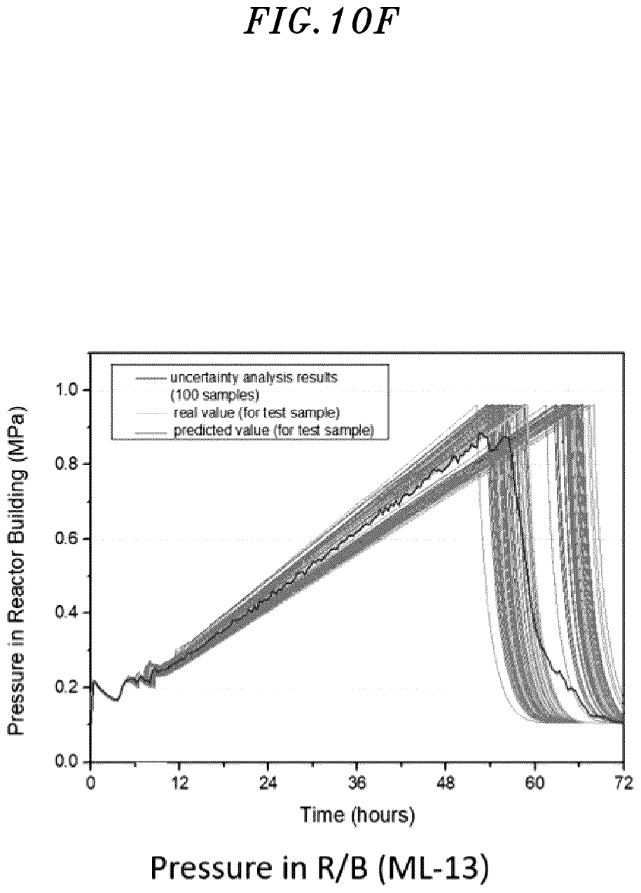

FIGS. 10A to 10F are simulation graphs showing results of predicting water levels and pressures in a reactor building for detailed scenarios of a medium coolant loss accident in the severe accident prediction process S108 of FIG. 6.

As illustrated in FIGS. 10A to 10F, for medium coolant loss accident detailed scenarios #7, #9, and #13, a water level and a pressure in the reactor building in the future (up to 72 hours) can be predicted with some initial water levels and reactor building pressure data (data of 30,000 seconds, approximately 8.3 hours in the example). In FIGS. 10A to 10F, the solid line expressed in light color represents a true value, the solid line in dark color represents a predicted value, and the distribution expressed in dark color represents a result due to code uncertainty. If a predicted value falls within the dark-colored distribution, it can be verified that it is a meaningful prediction.

Thereafter, the severe accident diagnosis and prediction apparatus 10 may predict radioactive material release information on the basis of the input variables for the scenarios of the severe accident diagnosis results. To this end, the processor 100 may train the source term prediction learning model 148 such that the learning model 148 predicts radioactive material release information on the basis of the input variables for the scenarios of the severe accident diagnosis results of the severe accident diagnosis learning model 144 and outputs a source term prediction result (S110).

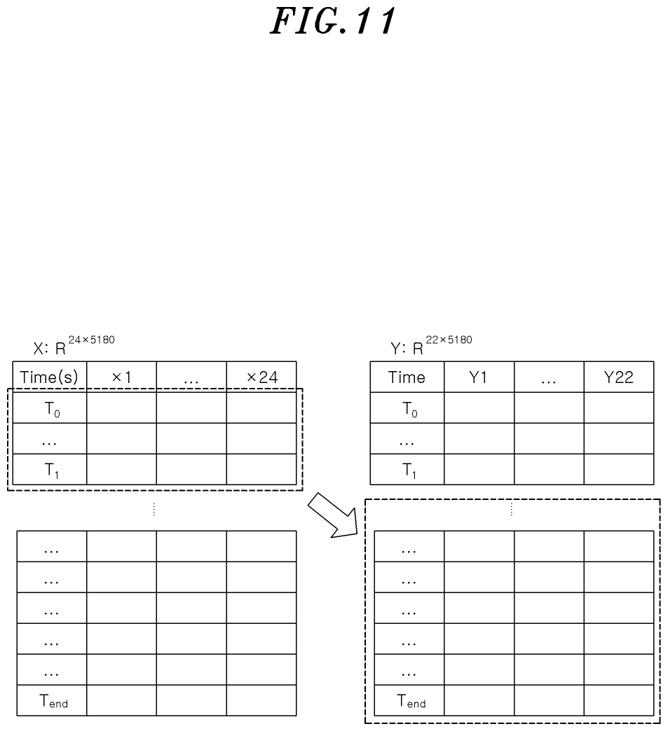

FIG. 11 is a conceptual diagram illustrating a problem of predicting cumulative environmental emissions of major elements through nuclear power plant data in the source term prediction process S110 of FIG. 6.

A learning model is developed and trained by setting nuclear power plant variables coming from the power plant defined in the acquisition unit 110 as input to artificial intelligence and setting release information on radioactive materials released into the environment due to occurrence of a severe accident as output of artificial intelligence. Release information may be information on various release characteristics, such as energy and particle size distribution as well as the amounts of release of major radionuclides (Xe, I, Cs, etc.) over time. FIG. 11 shows that source term information (for example, cumulative environmental emissions) for 22 elements can be predicted using information on some initial time among nuclear power plant information (for example, 24 pieces of 72-hour time series data) received from a nuclear power plant. First, if a severe accident in a nuclear power plant is diagnosed and a target scenario is ascertained, the accuracy of source term prediction can be improved. As the length of nuclear power plant information received from a nuclear power plant increases, the accuracy of source term prediction is also improved.

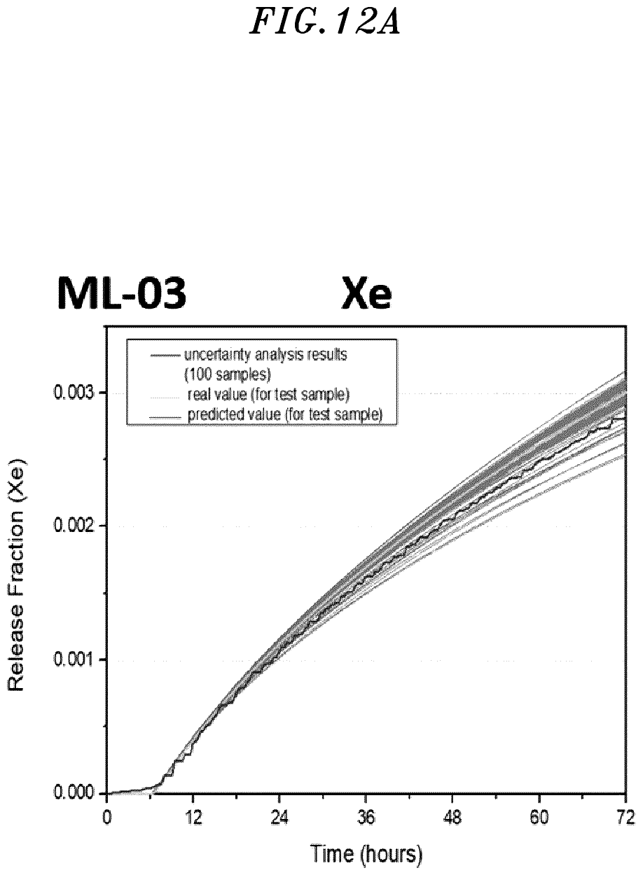

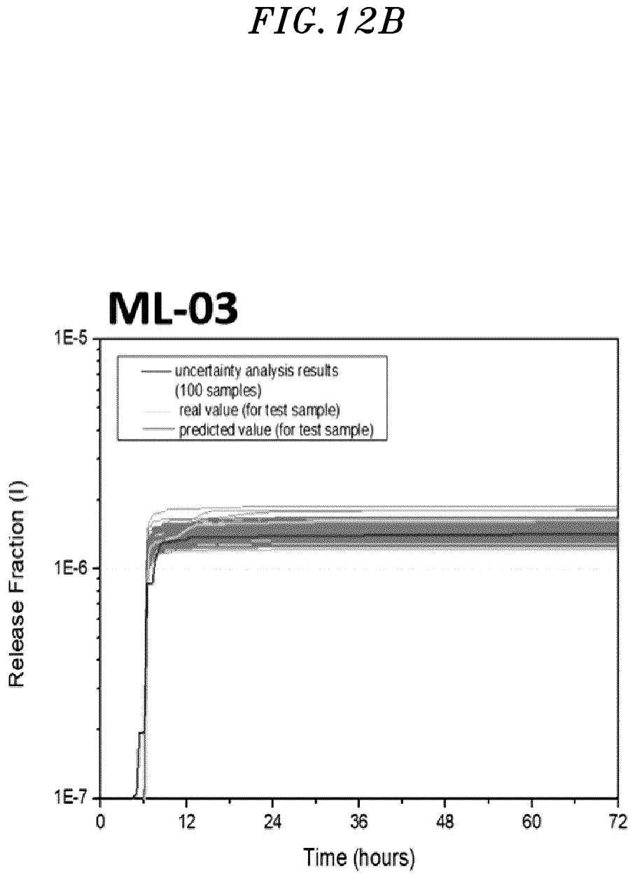

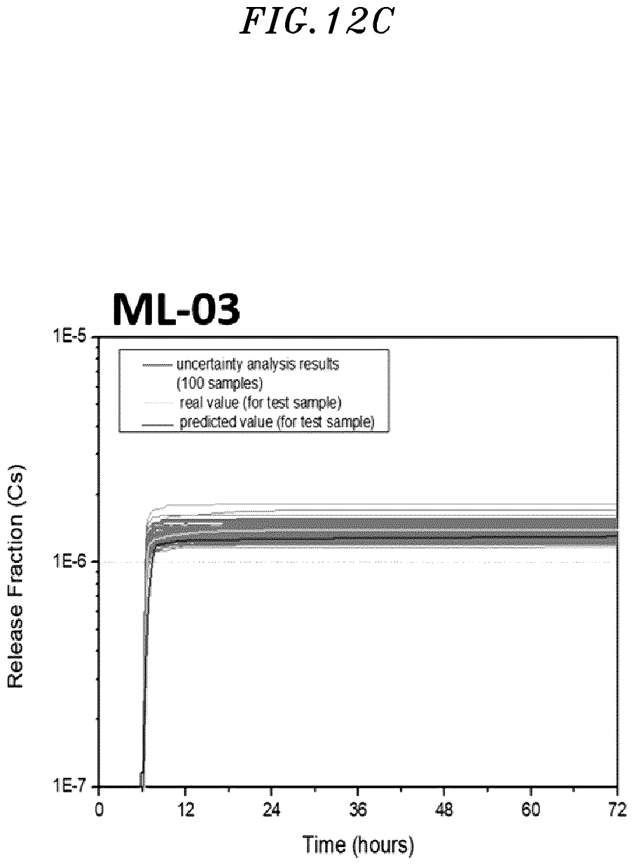

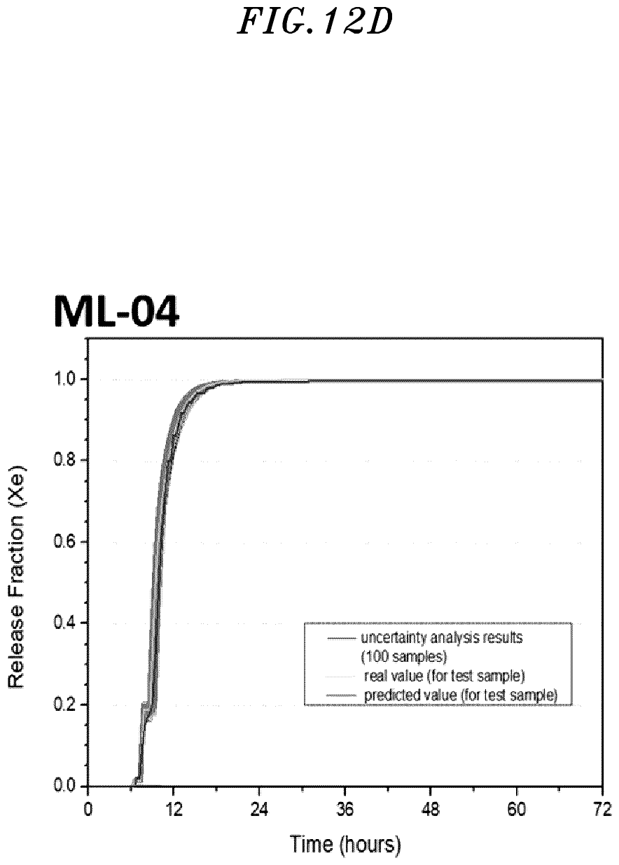

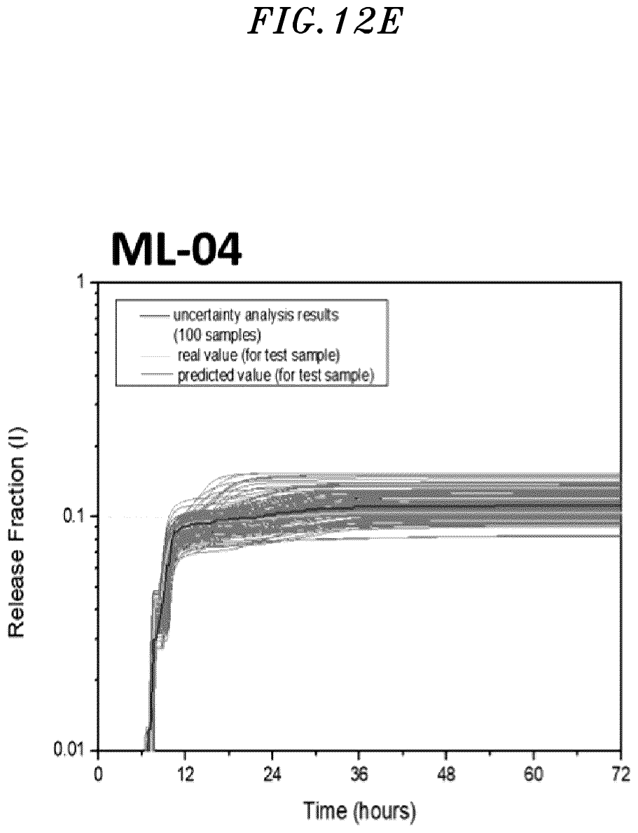

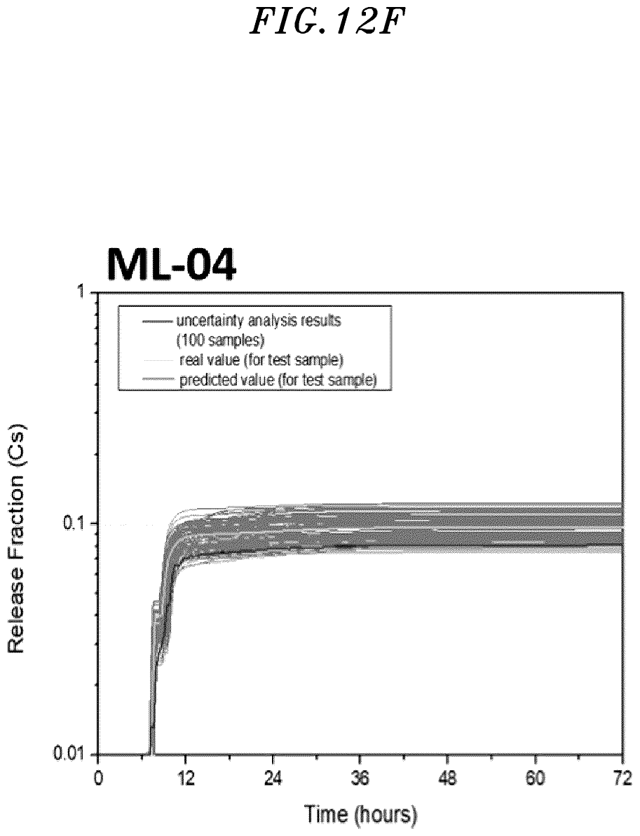

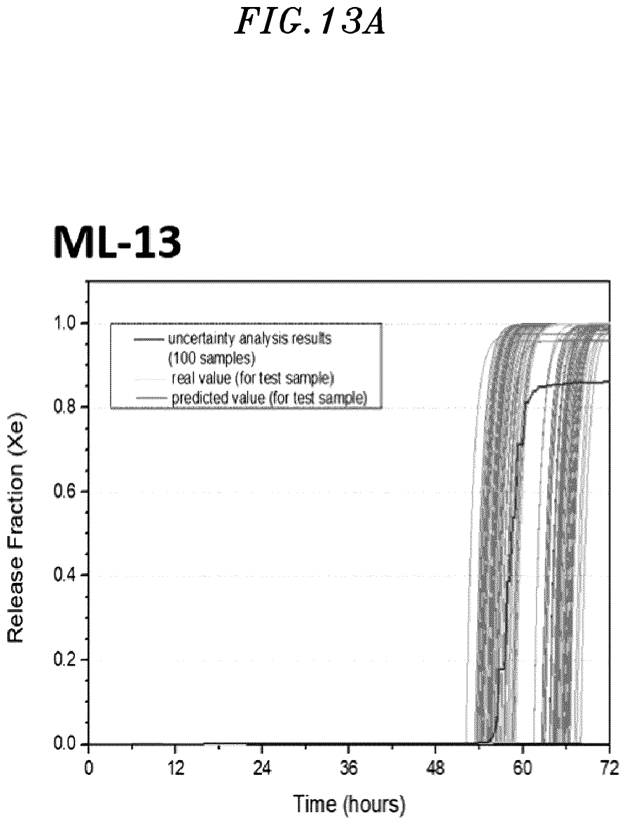

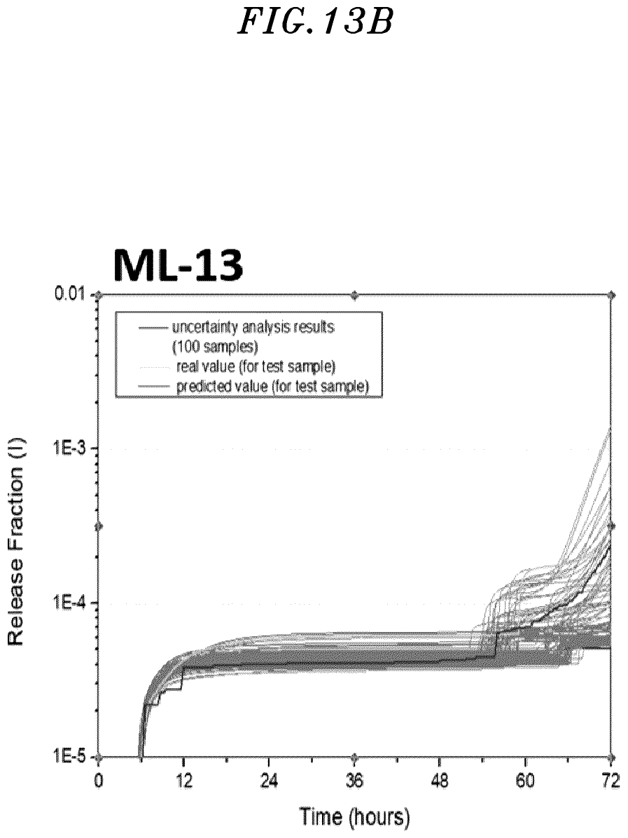

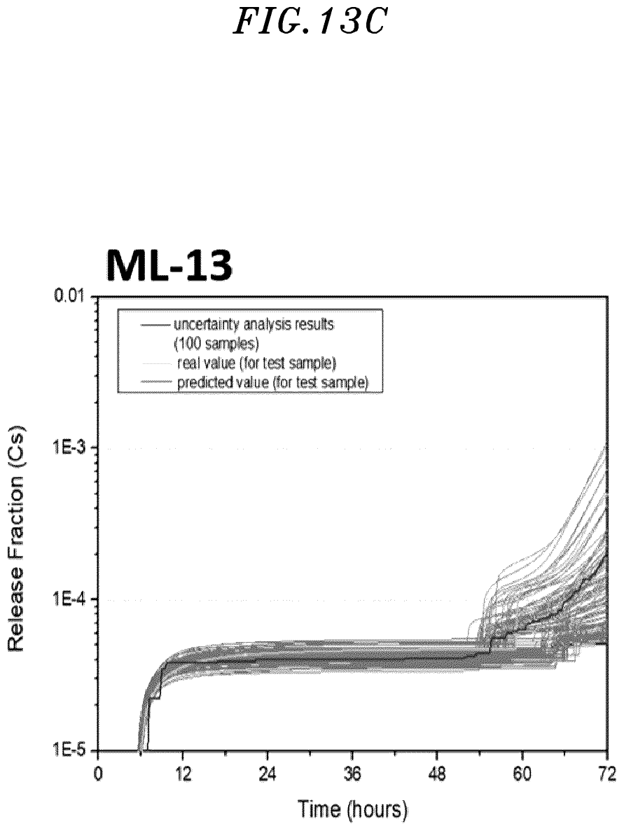

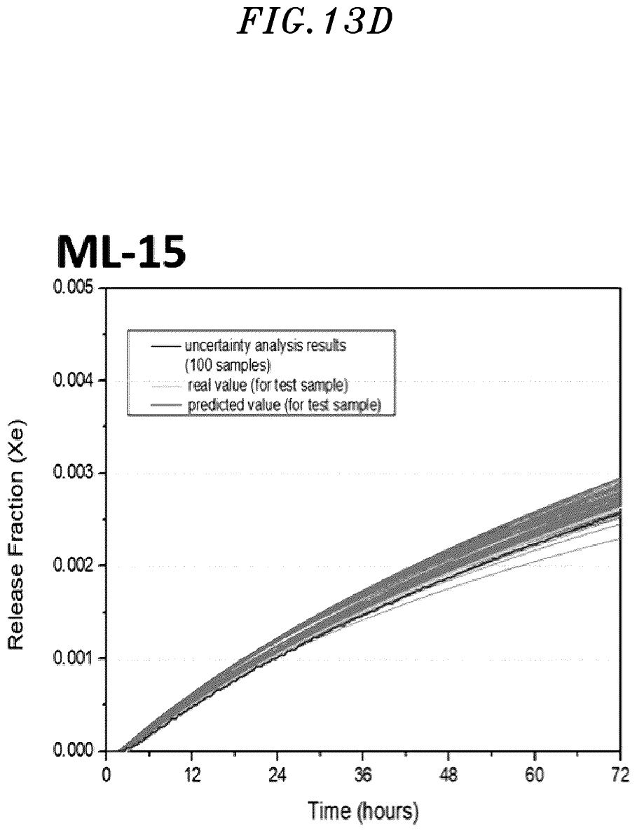

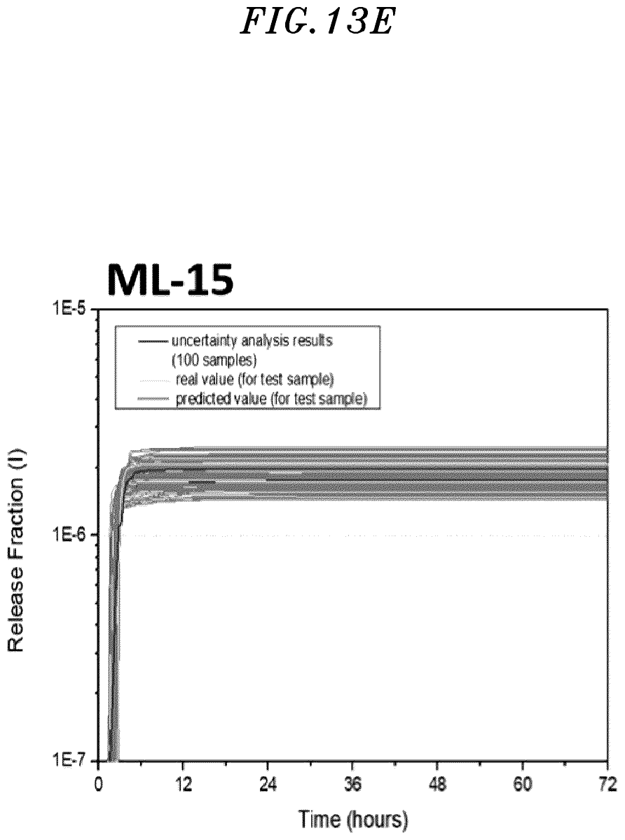

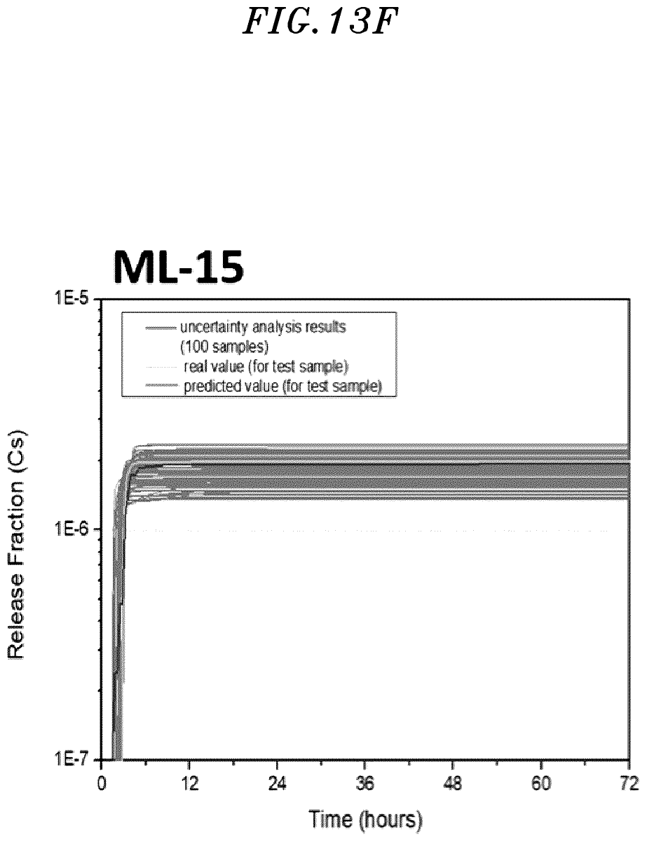

FIGS. 12A to 12F, and FIGS. 13A to 13F are conceptual diagrams illustrating a source term problem for major elements (Xe, I, and Cs) with respect to detailed scenarios of a medium coolant loss accident in the source term prediction process S110.

FIGS. 12A to 12F, and FIGS. 13A to 13F show results of prediction of cumulative environment emissions of Xe, I, and Cs in the future with some initial nuclear power plant information (for example, 24 pieces of nuclear power plant data of 30,000 seconds, approximately 8.3 hours) for detailed scenarios #3, #4, #13, and #15 of a medium coolant loss accident. In FIGS. 12A to 12F, and FIGS. 13A to 13F, the solid line expressed in light color represents a true value, the solid line in dark color represents a predicted value, and the distribution expressed in dark color represents a result of code uncertainty. If a predicted value falls within the dark-colored distribution, it can be verified that it is a meaningful prediction.

The severe accident diagnosis learning model 144, the severe accident prediction model 146, and the source term prediction learning model 148 are characterized in that the accuracy of diagnosis and prediction is improved as the time of data coming from a nuclear power plant increases rather than the time of some initial data is fixed.

As described above, according to an embodiment of the present disclosure, it is possible to systematically and efficiently apply severe accident scenarios with the number of various cases and to sufficiently consider phenomenological uncertainty inherent in producing big data for accident diagnosis and accident prediction in nuclear power plants by providing a severe accident diagnosis and prediction environment for nuclear power plants using a learning model based on artificial intelligence and proposing a learning technology for training an artificial intelligence model to perform diagnosis of a severe accident in a nuclear power plant, severe accident prediction, and source term prediction. In addition, according to an embodiment of the present disclosure, it is possible to perform a timely accident management strategy (guideline), and after rapid/accurate accident diagnosis and accident prediction, predict even an accident source term which is information on release of radioactive materials to support optimized decision-making for resident protection measures around a nuclear power plant.

Combinations of steps in each flowchart attached to the present disclosure may be executed by computer program instructions. Since the computer program instructions can be mounted on a processor of a general-purpose computer, a special purpose computer, or other programmable data processing equipment, the instructions executed by the processor of the computer or other programmable data processing equipment create a means for performing the functions described in each step of the flowchart. The computer program instructions can also be stored on a computer-usable or computer-readable storage medium which can be directed to a computer or other programmable data processing equipment to implement a function in a specific manner. Accordingly, the instructions stored on the computer-usable or computer-readable recording medium can also produce an article of manufacture containing an instruction means which performs the functions described in each step of the flowchart. The computer program instructions can also be mounted on a computer or other programmable data processing equipment. Accordingly, a series of operational steps are performed on a computer or other programmable data processing equipment to create a computer-executable process, and it is also possible for instructions to perform a computer or other programmable data processing equipment to provide steps for performing the functions described in each step of the flowchart.

In addition, each step may represent a module, a segment, or a portion of codes which contains one or more executable instructions for executing the specified logical function(s). It should also be noted that in some alternative embodiments, the functions mentioned in the steps may occur out of order. For example, two steps illustrated in succession may in fact be performed substantially simultaneously, or the steps may sometimes be performed in a reverse order depending on the corresponding function.

The above description is merely exemplary description of the technical scope of the present disclosure, and it will be understood by those skilled in the art that various changes and modifications can be made without departing from original characteristics of the present disclosure. Therefore, the embodiments disclosed in the present disclosure are intended to explain, not to limit, the technical scope of the present disclosure, and the technical scope of the present disclosure is not limited by the embodiments. The protection scope of the present disclosure should be interpreted based on the following claims and it should be appreciated that all technical scopes included within a range equivalent thereto are included in the protection scope of the present disclosure.

What is claimed is:

1. An apparatus for diagnosis and prediction of a severe accident in a nuclear power plant, comprising:
a classification unit configured to derive a plurality of scenarios for diagnosis and prediction of the severe accident in the nuclear power plant;
a strorage medium storing instructions for executing a method for diagnosis and prediction of the severe accident in the nuclear power plant using a learning model trained by a training database including training input variables for the plurality of scenarios and severe accident diagnosis and prediction information corresponding to the training input variables; and
a processor executing the one or more instructions stored in the strorage medium, wherein the instructions, when executed by the processor, cause the processor to obtain diagnostic input variables for the diagnosis and prediction of the severe accident in the nuclear power plant, input the diagnostic input variables into the learning model to check the severe accident diagnosis and prediction information, and output the checked severe accident diagnosis and prediction information.

2. The apparatus of claim 1, wherein the learning model includes:
a severe accident prediction learning model trained to receive the training input variables, predict changes in the training input variables, and output a severe accident prediction result; and
a source term prediction learning model trained to receive the training input variables and output a source term prediction result for predicting radioactive material release information.

3. The apparatus of claim 2, wherein the learning model further includes a severe accident diagnosis learning model trained to classify the training input variables corresponding to the scenarios and outputs a severe accident diagnosis result,
wherein the severe accident prediction learning model is trained to output results of prediction of changes in the training input variables on the basis of the severe accident diagnosis result provided from the severe accident diagnosis learning model, and
wherein the source term prediction learning model is trained to output the source term prediction result for predicting radioactive material release information on the basis of the training input variables for the scenarios with respect to the severe accident diagnosis result provided from the severe accident diagnosis learning model.

4. The apparatus of claim 1, wherein the diagnostic input variables include time series data related to status information of the nuclear power plant.

5. The apparatus of claim 1, wherein the scenarios are derived based on probabilistic safety assessment (PSA).

6. The apparatus of claim 5, wherein the scenarios are classified into detailed scenario of initiating events according to the probabilistic safety assessment on the basis of a plant damage state event tree (PDS ET) technique.

7. The apparatus of claim 1, wherein the processor is configured to construct the training database in which uncertainty is analyzed for each of the scenarios and stores the training database in a database unit.

8. The apparatus of claim 7, wherein the uncertainty includes phenomenon analysis code uncertainty and analysis scenario uncertainty.

9. A method for diagnosis and prediction of a severe accident in a nuclear power plant performed by an apparatus for diagnosis and prediction of a a severe accident in a nuclear power plant including a memory and a processor, the apparatus configured to derive a plurality of scenarios for diagnosis and prediction of the severe accident in the nuclear power plant, and store a learning model trained using a training database including training input variables for the plurality of scenarios and severe accident diagnosis and prediction information corresponding to the training input variables,
the method comprising:
obtaining diagnostic input variables for the diagnosis and prediction of the severe accident in the nuclear power plant; and
performing processing to input the diagnostic input variables into the learning model in the memory to check the severe accident diagnosis and prediction information and output the checked severe accident diagnosis and prediction information.

10. The method of claim 9, wherein the learning model includes:
a severe accident prediction learning model trained to receive the training input variables, predict changes in the training input variables, and output a severe accident prediction result; and
a source term prediction learning model trained to receive the training input variables and output a source term prediction result for predicting radioactive material release information.

11. The method of claim 9, wherein the learning model further includes a severe accident diagnosis learning model trained to classify the training input variables corresponding the scenarios and output a severe accident diagnosis result, and
wherein the performing processing includes:
outputting results of prediction of changes in the diagnostic input variables on the basis of the severe accident diagnosis result provided from the severe accident diagnosis learning model using the severe accident prediction learning model; and
outputting a source term prediction result for predicting radioactive material release information on the basis of the diagnostic input variables for the scenarios with respect to the severe accident diagnosis result provided from the severe accident diagnosis learning model using the source term prediction learning model.

12. The method of claim 9, wherein the diagnostic input variables include time series data related to status information of the nuclear power plant.

13. The method of claim 9, wherein the scenarios are derived based on probabilistic safety assessment.

14. The method of claim 13, wherein the scenarios are classified into detailed scenario of initiating events according to the probabilistic safety assessment on the basis of a plant damage state event tree technique.

15. The method of claim 9, further comprising constructing the training database in which uncertainty is analyzed for each of the scenarios.

16. The method of claim 15, wherein the uncertainty includes phenomenon analysis code uncertainty and analysis scenario uncertainty.

17. A non-transitory computer-readable storage medium storing computer executable instructions, wherein the instructions, when executed by a processor, cause the processor to perform a method for training a learning model for diagnosis and prediction of a severe accident in a nuclear power plant, the method comprising:
preparing the learning model including a severe accident prediction learning model and a source term prediction learning model;
selecting training input variables for the diagnosis and prediction of the severe accident in the nuclear power plant;
deriving a plurality of scenarios for the diagnosis and prediction of the severe accident in the nuclear power plant;
constructing a training database for each scenario;
inputting the training input variables into the severe accident prediction learning model and training the severe accident prediction learning model to predict changes in the training input variables and output a severe accident prediction result; and
inputting the training input variables into the source term prediction learning model and training the source term prediction learning model to predict radioactive material release information and output a source term prediction result.

18. The computer-readable recording medium of claim 17, wherein the learning model further includes a severe accident diagnosis learning model trained to classify the training input variables corresponding to the scenarios and outputs a severe accident diagnosis result,
wherein the training of the severe accident prediction learning model includes training the severe accident prediction learning model to output results of prediction of changes in the training input variables using the severe accident diagnosis result provided from the severe accident diagnosis learning model, and
wherein the training of the source term prediction learning model includes training the source term prediction learning model to output radioactive material release information using the training input variables for the scenarios of the severe accident diagnosis result provided from the severe accident diagnosis learning model.

19. The computer-readable recording medium of claim 17, wherein the training input variables include time series data related to status information of the nuclear power plant.

20. The computer-readable recording medium of claim 17, wherein the scenarios are derived based on probabilistic safety assessment (PSA).
